(19) United States
(12) Patent Application Publication
(10) Pub. No.: US 2007/0119497 A1
(43) Pub. Date: May 31, 2007

(54) PHOTOELECTROMOTIVE FORCE APPARATUS AND MANUFACTURING METHOD THEREOF

(75) Inventors: Seiji Umemoto, Ibaraki-shi (JP); Akira Ootani, Ibaraki-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: NITTO DENKO CORPORATION, Ibaraki-shi (JP)

(21) Appl. No.: 11/564,529

(22) Filed: Nov. 29, 2006

(30) Foreign Application Priority Data
Nov. 29, 2005 (JP) 2005-344111

(51) Int. Cl. H01L 31/00

(52) U.S. Cl. 136/252

(57) ABSTRACT

A photoelectromotive force apparatus according to the prevent invention includes a solar cell in which a p-type semiconductor layer and an n-type semiconductor layer are stacked as photoelectromotive force layers between a pair of electrodes that are disposed to oppose each other, wherein The pn-junction between the p-type semiconductor layer and the n-type semiconductor layer has an end side in the photoreceptive surface, and is tilted relative to the photoreceptive surface.

### BACKGROUND OF THE INVENTION

1. Field of the Invention

The present invention relates to a photoelectronics device, and more particularly to a photoelectromotive force apparatus of pn-junction type using a semiconductor and a method thereof.

2. Description of the Related Art

In order to achieve a goal of carbon dioxide reduction and to prevent global warming, use of a solar cell (photoelectromotive force apparatus) is expected. The solar cells can be roughly classified into an inorganic semiconductor solar cells, organic semiconductor solar cells, and dye-sensitized solar cells (Graetzel cells).

An inorganic semiconductor solar cell has a high photoelectric conversion efficiency of 20%, and has already been put into practical use. However, the high production cost thereof inhibits the enlargement of the market. A dye-sensitized solar cell has a photoelectric conversion efficiency of about 10%, and is basically a wet-type solar cell. For this reason, the dye-sensitized solar cell has a problem in the durability. On the other hand, a pn-junction type photoelectromotive force apparatus using an organic semiconductor is referred to as an organic solar cell, and has a basic principle in which the photocarriers generated at the pn-junction are taken out as an electric current. The solar cells of this type have a low conversion efficiency of several %, though these cells can be manufactured in a comparatively simple manner.

A typical example of a conventional organic solar cell will be shown in FIG. 1 (C. W. Tang, Appl. Phys. Lett., 48, 183 (1986)). As shown in FIG. 1, a conventional plane junction type organic solar cell 100 is constructed in such a manner that a p-type organic semiconductor layer 102 and an n-type organic semiconductor layer 104 are stacked between a pair of electrodes 101 and 105. Also, at the boundary of the p-type organic semiconductor layer 102 and the n-type organic semiconductor layer 104, a pn-junction 103 is formed. The p-type organic semiconductor layer 102 is made of phthalocyanine (H₂Pc) that is not substituted with a metal.

The n-type organic semiconductor layer 104 is made of an N-methyl-3,4,9,10-perylene-tetracarboxyldiimide derivative (Me-PTC, see the following chemical structural formula). As the electrode 101 that is in contact with the p-type organic semiconductor layer 102, an ITO (indium tin oxide) transparent electrode is used. As the electrode 105 that is in contact with the n-type organic semiconductor layer 104, a gold (Au) electrode is used.

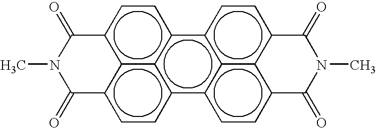

The organic solar cell 100 shown in FIG. 1 is constructed in such a manner that the pn-junction 103 will be parallel to the photoreceptive surface 107 that is irradiated with incident light 106. With such a construction, the active region of photocarrier generation has an extremely small thickness, and is extended to only about several ten nm on the two sides of the pn-junction 103. Moreover, the internal resistance of the element is extremely high. Therefore, the photoelectric energy conversion efficiency is below or equal to 1%, which is a value far from that for practical use.

Also, there is an attempt of a tandemized cell in which two or more pnjunction cells are stacked (M. Hiramoto, M. Suezaki, M. Yokoyama, Chem. Lett., 1990, 327 (1990).); however, it has not been leading to great improvement of photoelectric energy conversion efficiency.

The major causes of low photoelectric energy conversion efficiency of an organic solar cell may be, for example, extremely small thickness of the active region of photocarrier generation and extremely high internal resistance. Serious effects that these causes provoke on the cell characteristics of the structure shown in FIG. 1 can be listed as follows.

(1) Only the neighborhood of the pn-junction is photoactive. Therefore, when a film having a larger thickness than the width of the active region is fabricated, the extra thick part thereof will be an inactive layer that does not generate photoelectric current even if the part absorbs light. This inactive layer absorbs a lot of light, so that only a slight amount of light reaches the active pn-junction that can generate photoelectric current. In other words, in a conventional solar cell, only a slight amount of photoelectric current is generated due to such a masking effect.

(2) When the cell thickness is reduced to avoid the aforementioned masking effect, for example, when the organic semiconductor layers 102 and 104 are made to have an extremely small film thickness of several ten nm, electric conduction of the cell (electric contact between the electrode 101 and the electrode 105) will occur easily, so that the cell will not function as a solar cell.

(3) Also, even if the reduction of the cell thickness can be realized, with a thin active layer, most of the incident light 106 will be transmitted through the cell without being absorbed, so that the photoelectric energy conversion efficiency will not be improved.

(4) When the organic semiconductor layer is thick, the part in the rear of the film into which the light cannot penetrate due to the absorption by the organic semiconductor layer is in a dark state. In a dark state, organic semiconductor exhibits an electric resistance close to that of an insulator. For this reason, if one attempts to allow all of the incident light 106 to be absorbed by increasing the cell thickness, the internal resistance will be extremely high. On the other hand, photoelectric current cannot reach the electrode without passing through that high-resistance part. As a result of this, there will be a considerable decrease in the photoelectric current density, the curved line factor (FF: Fill Factor), and the photoelectromotive voltage.

In order to solve these problems fundamentally, it is necessary to realize a cell in which much of the incident light is absorbed in the active region in the neighborhood of the pn-junction and in which the internal resistance is low.

On the other hand, in order to solve these problems, Japanese Patent Application Laid-Open (JP-A) Gazette No. 2005-11841 discloses a photoelectromotive force apparatus of a vertical junction type having a cell 108 that is constructed in such a manner that a p-type organic semiconductor layer 110 and an n-type organic semiconductor layer 112 are stacked between a pair of metal electrodes 109 and 113 (See FIG. 2). The cell is formed in such a manner that the pn-junction 111 formed at the boundary between the p-type organic semiconductor layer 110 and the n-type organic semiconductor layer 112 will be vertical to the photoreceptive surface 107. The Patent Application Gazette also discloses a method of connecting these cells 108 in series.

This Patent Application Gazette No. 2005-11841 discloses that the photoelectric current density will increase, and that the cell is optimized by reducing the thickness of the organic semiconductor layers to be below or equal to 100 nm. The reason is that the photoelectric current is generated only in the neighborhood of the pn-junction 111 (active region of 50 nm located to the right and to the left of the pn-junction 111 with the pn-junction 111 sandwiched therebetween, i.e. the active region having a thickness of the sum of about 100 nm), and the width of 400 nm among the total width of 500 nm of the organic semiconductor layers does not contribute to the photocarrier generation, and only the carriers flow therethrough. For this reason, an extremely large photoelectric current density will be obtained if the cell film thickness can be reduced to 100 nm; however, it is difficult to obtain a thin film that is uniform without pinholes, thereby raising a problem in that the electric conduction of the cell will occur easily.

Also, with the structure in which the pn-junction is of the vertical junction type such as described above, the area of the active region to the photoreceptive surface 107 is extremely small, thereby being inefficient with regard to the use of optical energy. It will be readily understood that the area of incidence to the photoreceptive surface 107 of a solar cell will be the maximum when the photoreceptive surface 107 is vertical to the progression direction of the incident light. However, in the Japanese Patent Application Laid-Open Gazette No. 2005-11841, the active region provided by the pn-junction 111 (the region having a width narrower than about 100 nm with the pn-junction 111 sandwiched as a center) is formed vertically. Therefore, when it is set that the photoreceptive surface 107 will have the maximum photoreceptive area, the active region will be extremely narrow, as described above. For this reason, the projection area to the light beam will be extremely small, thereby raising a problem in that the electromotive force and the photoelectric current will be small. Also, the light incident into a region other than the active region is absorbed in an inactive region with little incidence into the active region. For this reason, the photoelectric energy conversion efficiency is low.

On the other hand, if it is attempted to increase the projection area of the active region to the light beam, it is necessary to let the light be incident in a tilted direction relative to the photoreceptive surface of the solar cell. However, in this case, the photoreceptive area of the photoreceptive surface will be small, thereby leading to decrease in the amount of received light.

Moreover, the optical path of the light incident into the cell changes by refraction. In the inside of the solar cell having a far larger refractive index than the refractive index of air, the angle of refraction will be smaller than the angle of incidence, so that the projection area of the active region will not be so large. Therefore, the efficiency of the use of light in the case of allowing the light to be obliquely incident is not high.

### SUMMARY OF THE INVENTION

The present invention has been made in order to solve the aforementioned problems of the prior art, and an object thereof is to provide a photoelectromotive force apparatus that can improve the photoelectric energy conversion efficiency and can generate a larger photoelectromotive force as compared with a conventional organic semiconductor solar cell, as well as a method of manufacturing the same.

The inventors of the present invention and others have made eager studies on photoelectromotive force apparatus and a manufacturing method thereof in order to solve the aforementioned problems of the prior art. As a result of this, it has been found out that the aforementioned object can be achieved by adopting the following construction, thereby completing the present invention.

Namely, in order to solve the aforementioned problems, the photoelectromotive force apparatus of the present invention is a photoelectromotive force apparatus including a solar cell in which a p-type semiconductor layer and an n-type semiconductor layer are stacked as photoelectromotive force layers between a pair of electrodes that are disposed to oppose each other, wherein a pn-junction between the p-type semiconductor layer and the n-type semiconductor layer has an end side in a photoreceptive surface, and is tilted relative to the photoreceptive surface.

In the aforesaid construction, the pn-junction is provided to be in a tilted direction relative to the photoreceptive surface. Therefore, a so-called masking effect, in which the amount of light reaching the active region in the neighborhood of the pn-junction (for example, the region having a width narrower than about 100 nm with the pn-junction sandwiched as a center) decreases due to photoabsorption of the light penetrating into the cell by the inactive region of the p-type semiconductor layer or the n-type semiconductor layer as in the case in which the pn-junction is of a plane junction type, will not occur. Also, the active region relative to the photoreceptive surface can be prevented from becoming small as in the case in which the pn-junction is of a vertical junction type, and can improve the phototransmittance efficiency in the active region. Further, the projection area of the active region to the light beam can be increased without reducing the photoreceptive area of the photoreceptive surface. Namely, the area efficiency of the photoreceptive area can be improved. This allows that much of the received light will be photoabsorbed by the active region, thereby contributing to the generation of photoelectric current. This achieves a great improvement in the photoelectric energy conversion efficiency as compared with a conventional organic semiconductor solar cell.

In the aforesaid construction, it is preferable that an angle formed by a normal line to the pn-junction and a normal line to the photoreceptive surface is above or equal to 30° and below or equal to 60°.

By allowing the angle formed by a normal line to the pn-junction and a normal line to the photoreceptive surface to be above or equal to 30°, the loss caused by the masking effect can be restrained, and the photoelectric energy conversion efficiency can be improved. Further, in the neighborhood of the photoreceptive surface, the increase in the internal resistance in the neighborhood of the photoreceptive surface due to excessively large distance between the active region and the pair of electrodes can be restrained. Also, the angle to be below or equal to 60° can prevent the area of the active region to the photoreceptive surface from becoming excessively small, thereby making it possible to use the energy of light more efficiently.

Also, in the aforesaid construction, it is preferable that a plurality of the solar cells are stacked in series so that the pn-junctions will be parallel to each other.

Also, in the aforesaid construction, it is preferable that a material of the aforesaid pair of electrodes is selected so that a work function of the electrode that is in contact with the p-type semiconductor layer will be larger than a work function of the electrode that is in contact with the n-type semiconductor layer.

Thus, the junction between the pair of electrodes and the p-type semiconductor layer and the n-type semiconductor layer is an ohmic junction so that the photoelectric current generated at the pn-junction can be efficiently taken out to the outside.

Also, in the aforesaid construction, it is preferable that at least one of the p-type semiconductor layer and the n-type semiconductor layer is an organic semiconductor layer.

In order to solve the aforementioned problems, the method of manufacturing a photoelectromotive force apparatus according to the present invention is a method of manufacturing a photoelectromotive force apparatus, including the steps of: stacking an electrode on a substrate; stacking a p-type semiconductor layer on said electrode; stacking an n-type semiconductor layer on said p-type semiconductor layer to form a pn-junction; stacking another electrode on said n-type semiconductor layer; and cutting a stacked product formed through at least said steps so that a cut surface will be tilted relative to a surface of the stacked product to form a photoreceptive surface.

With the aforesaid method, after the electrode, the p-type semiconductor layer, the n-type semiconductor layer, and another metal are successively stacked on a substrate to form a stacked product, this stacked product is cut in a tilted direction of a predetermined angle to the front surface or rear surface thereof. Through this step, the pn-junction formed between the p-type semiconductor layer and the n-type semiconductor layer will have an end side in a photoreceptive surface, and will be tilted relative to the photoreceptive surface.

Namely, by the above method, a photoelectromotive force apparatus having a structure such that the pn-junction is tilted relative to the photoreceptive surface will be obtained, so that the loss caused by the so-called masking effect will be reduced, thereby making it possible to manufacture a photoelectromotive force apparatus having a higher photoelectric energy conversion efficiency as compared with a conventional organic semiconductor solar cell.

In the above method, it is preferable that the step of cutting the stacked product is carried out by setting a cutting direction so that an angle formed by a normal line to the pn-junction and a normal line to the cut surface will be above or equal to 30° and below or equal to 60°.

By setting the cutting direction of the stacked product as in the above method, a photoelectromotive force apparatus can be manufactured in which the loss caused by the masking effect is restrained; the photoelectric energy conversion efficiency is further improved; and the area of the active region of photocarrier generation to the photoreceptive surface is prevented from becoming excessively small, thereby making it possible to use the energy of light more efficiently.

In the above method, it is preferable that the step of cutting the stacked product is carried out from an end surface side of the stacked product.

By the above method, the cutting step can be carried out so that none of the metal, the p-type semiconductor layer, the n-type semiconductor layer, and the other metal will be peeled off in the cutting step. As a result of this, the photoelectromotive force apparatus can be manufactured with improved yield.

Here, another method of manufacturing a photoelectromotive force apparatus according to the present invention includes the steps of stacking an electrode on a substrate; stacking an n-type semiconductor layer on the electrode; stacking a p-type semiconductor layer on the n-type semiconductor layer to form a pn-junction; stacking another electrode on the p-type semiconductor layer; and at least cutting a stacked product formed through the steps so that a cut surface will be tilted relative to a surface of the stacked product to form a photoreceptive surface. Even with this method, effects similar to those of the aforementioned manufacturing method can be produced.

The photoelectromotive force apparatus of the present invention has a structure such that the pn-junction thereof has an end side in the photoreceptive surface, and is tilted at a predetermined angle relative to the photoreceptive surface, thereby improving the phototransmittance efficiency at the active region in the neighborhood of the pn-junction and increasing the area efficiency of the photoreceptive area. As a result of this, the photoelectric energy conversion efficiency can be greatly improved as compared with a conventional organic semiconductor solar cell.

Also, with the method of manufacturing a photoelectromotive force apparatus of the present invention, a stacked product, which is obtained by successively stacking an electrode, a p-type semiconductor layer, an n-type semiconductor layer, and another metal on a substrate, is cut so that the cut surface will be tilted relative to the surface of the stacked product, thereby achieving a structure in which the pn-junction is tilted relative to the photoreceptive surface. Namely, with the manufacturing method of the present invention, a photoelectromotive force apparatus is obtained that can greatly improve the photoelectric energy conversion efficiency as compared with a conventional organic semiconductor solar cell.

### BRIEF DESCRIPTION OF THE DRAWINGS

FIG. 1 is a cross-sectional view schematically showing a structure of a conventional organic solar cell.

FIG. 2 is a cross-sectional view schematically showing a structure of another conventional organic solar cell.

FIG. 3 is a cross-sectional view schematically showing a structure of a solar cell according to an embodiment of the present invention.

FIG. 4 is a cross-sectional view showing a continuous stacking structure having the aforesaid solar cell as one unit.

FIG. 5 is a model view showing a state in which the aforesaid continuous stacking structure is formed into a roll.

FIG. 6 is a descriptive view for describing a method of manufacturing the aforesaid solar cell.

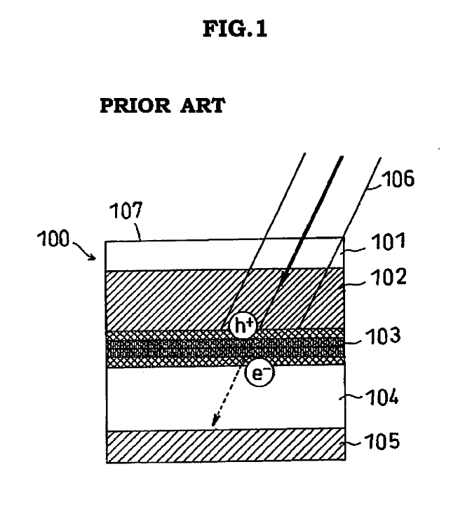

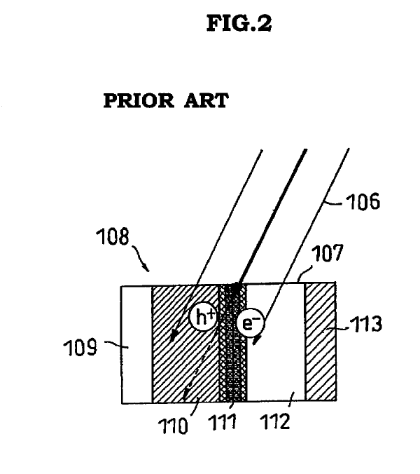

### DESCRIPTION OF THE EMBODIMENTS

Hereafter, embodiments of the present invention will be described with reference to the attached drawings. However, parts not needed for description will be omitted, and some parts are illustrated by being enlarged or diminished for simplifying the description.

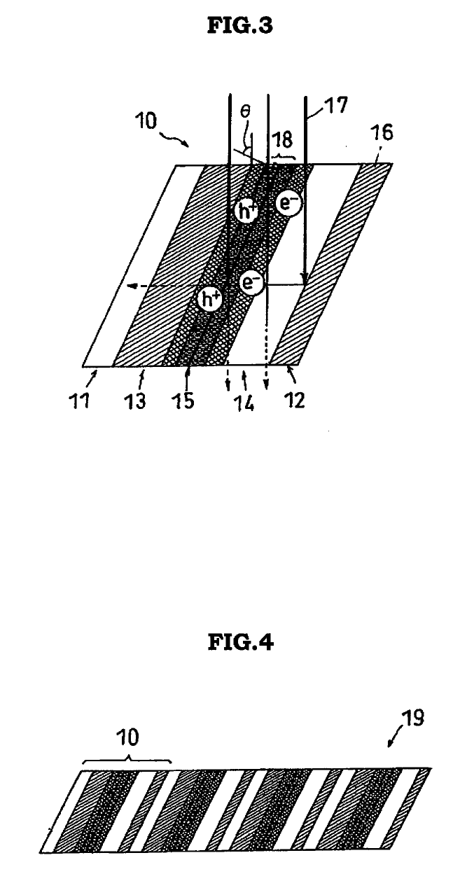

A photoelectromotive force apparatus according to the present embodiment is a solar cell of tilted junction type provided with a solar cell 10 shown in FIG. 3. The solar cell 10 has a structure of a stacked product in which a p-type semiconductor layer 13 and an n-type semiconductor layer 14 are stacked as photoelectromotive force layers between a first electrode 11 and a second electrode 12.

As the aforesaid p-type semiconductor layer 13, an organic semiconductor layer is preferable. Examples of the constituent materials for making the p-type semiconductor layer 13 with an organic semiconductor layer include phthalocyanines including non-metal phthalocyanine (H₂Pc) and metal-substituted phthalocyanine (MPc) such as TiOPc, quinacridones and others, fullerene derivatives, polyphenylene derivatives, polyphenylenevinylene derivatives, polythiophene derivatives, polyaniline derivatives, polypyrrole derivatives, and the like.

As the aforesaid n-type semiconductor layer 14, an organic semiconductor layer is preferable, as in the case of the p-type semiconductor layer 13. Examples of the constituent materials for making the n-type semiconductor layer 14 with an organic semiconductor layer include perylene derivatives, naphthalene derivatives, fullerene derivatives, and the like.

The pn-junction 15 formed at the boundary between the p-type semiconductor layer 13 and the n-type semiconductor layer 14 has an end side in a photoreceptive surface 16 (surface irradiated with light), and is tilted at a predetermined angle relative to the photoreceptive surface 16. By this, the light 17 incident in a vertical direction relative to the photoreceptive surface 16 can be made to be incident obliquely relative to the active region 18 (for example, a region having a width narrower than about 100 nm with the pn-junction 15 sandwiched as a center). With the structure such that the pn-junction is vertical to the photoreceptive surface as in the conventional solar cell (See Japanese Patent Application Laid-Open No. 2005-11841), almost all of the light incident in the vertical direction relative to the photoreceptive surface will be absorbed in an inactive region, leading to low efficiency of the use of light and to a large loss. However, when the pn-junction 15 is tilted relative to the photoreceptive surface 16 as in the present embodiment, the light 17 incident in the vertical direction relative to the photoreceptive surface 16 will be efficiently absorbed in the active region 18 in the neighborhood of the pn-junction 15, whereby the loss caused by the masking effect is reduced, and most of the light 17 is absorbed in the active region, thereby contributing to the generation of photoelectric current. As a result of this, improvement in the photoelectric energy conversion efficiency can be achieved as compared with the aforementioned conventional organic semiconductor solar cell.

Also, the active region 18 is obliquely formed. Therefore, even if the light 17 is incident into an inactive region, the light 17 reaches the active region 18 in the process of propagating within the cell, thereby contributing to the generation of photoelectromotive force.

It is preferable that an angle θ formed by a normal line to the pn-junction 15 and a normal line to the photoreceptive surface 16 is above or equal to 30° and below or equal to 60°. When the angle θ is within the aforesaid range, the loss caused by the masking effect can be restrained, thereby further improving the photoelectric energy conversion efficiency. Further, in the neighborhood of the photoreceptive surface 16, the distance between the active region 18 and the first electrode 11 and the second electrode 12 can be prevented from becoming excessively large, whereby the increase in the internal resistance in the neighborhood of the photoreceptive surface 16 can be restrained. Also, the area of the active region 18 of photocarrier generation to the photoreceptive surface 16 can be prevented from becoming excessively small, thereby making it possible to use the energy of light more efficiently.

At least one of the p-type semiconductor layer 13 and the n-type semiconductor layer 14 may be formed to have a stacked structure in which organic semiconductor layers having different band structures are stacked to form a step-like energy structure, or may be formed to have a stacked structure in which organic semiconductor layers having different photoabsorption characteristics are stacked.

The materials for constructing the first electrode 11 and the second electrode 12 are not particularly limited, so that conventionally known ones may be adopted. However, it is preferable that the materials for constructing the first electrode 11 and the second electrode 12 are selected so that a work function of the first electrode 11 will be larger than a work function of the second electrode 12. As a metal having a large work function, Pt can be given as an example. As a metal having a small work function, In can be given as an example.

When the photoelectromotive force apparatus is constructed only with one unit structure of the solar cell 10 according to the present embodiment, it is preferable that the first electrode 11 is a transparent electrode, and the second electrode 12 is a metal electrode. This is because, when the first electrode 11 is a metal electrode, the incidence of light from the side surface of the solar cell 10 is inhibited by being photoreflected by the first electrode 11, thereby leading to decrease in the power generation efficiency. Also, by making the second electrode 12 with a metal electrode, the light incident into the solar cell 10 is photoreflected towards the active region 18 by the second electrode 12 serving as the metal electrode, thereby improving the efficiency of using light.

Also, in consideration of the propagation efficiency of the light that propagates through the inside of the solar cell 10, the smaller the photoabsorption by the first electrode 11 and the second electrode 12 is, the better it is. Also, the higher the photoreflectivity is, the better it is. By allowing the light to propagate while being subjected to multiple reflection at the first electrode 11 and the second electrode 12, the number of times at which the light passes through the active region 18 can be increased, thereby leading to an outstanding improvement in the power generation efficiency. From such a viewpoint, it is preferable that the first electrode 11 and the second electrode 12 are metal electrodes. When the electrodes 11 and 12 are formed of metal electrodes, the materials for the first electrode 11 and the second electrode 12 are preferably selected by considering both the viewpoint of work function and the viewpoint of small photoabsorption and high reflectivity together.

In the photoelectromotive force apparatus according to the present embodiment, when the structure made of transparent electrode (first electrode 11)/p-type semiconductor layer 13/n-type semiconductor layer 14/metal electrode (second electrode 12), for example, is a unit structure, the order of stacking the p-type semiconductor layer 13 and the n-type semiconductor layer 14 can be selected so that the energy level will be in an optimum state.

The photoreceptive surface 16 of the solar cell 10 according to the present embodiment is formed by the end surfaces of the first electrode 11, the second electrode 12, the p-type semiconductor layer 13 and the n-type semiconductor layer 14. Therefore, reception of light is carried out at the end surface of each layer. Also, since the solar cell 10 has a height of 1 mm or more and has a stacked structure in which each layer is tilted, the light of a wavelength region having a small absorption coefficient can be absorbed. Namely, the solar cell 10 can absorb the light 17 that is received in almost all wavelength regions. Here, when a conventional plane-junction type solar cell is simply tilted, the photoreceptive surface will be an electrode surface. Therefore, when such a photoreceptive surface is Irradiated with light, part of the light is surface-reflected at the electrode surface, leading to decrease in the amount of light penetrating into the inside of the cell. Also, since the cell itself is tilted, the photoreceptive area will be S cos θ assuming that the original surface area is S, thereby leading to decrease in the area efficiency.

Also, a protective layer having a predetermined thickness may be provided on the second electrode 12. The protective layer serves to prevent exfoliation of the interface between the first electrode 11 or the second electrode 12 and the p-type semiconductor layer 13 or the n-type semiconductor layer 14 at the time of cutting the stacked product with a microtome. The film of the protective layer can be formed, for example, by the vacuum vapor deposition method. Also, the thickness of the protective layer is not particularly limited. Further, as the material for constructing the protective layer, various organic or inorganic thin film materials can be used.

As shown in FIG. 4, the photoelectromotive force apparatus of the present invention may be made as a solar cell module 19 with a continuous stacking structure having the solar cell 10 as one unit. In this case, a plurality of the solar cells 10 are stacked in series so that the pn-junctions 15 will be parallel to each other at an interval of, for example, 100 nm. With the continuous stacking structure, all of the photoreceptive surface will function as an active region. As a result of this, the loss of light can be essentially eliminated, and all of the received light 17 can be effectively used, thereby leading to an improvement in the photocurrent generation efficiency.

More specifically, the solar module 19 shown in FIG. 4 may be, for example, Pt/H₂Pc layer (thickness: 50 nm)/Me-PTC layer (thickness: 50 nm)/Au layer (thickness: 1 nm)/ H₂Pc layer (thickness: 50 nm)/Me-PTC layer (thickness: 50 nm)/Au layer (thickness: 1 nm)/ . . . H₂Pc/Me-PTC/In/Ag. By forming the structure shown in FIG. 4, the problem of the masking effect can be fundamentally solved.

When a continuous stacking structure having the solar cell 10 as one unit is to be formed, it is preferable that the structure is formed so that the semiconductor layer having the higher optical transparency among the p-type semiconductor layer 13 and the n-type semiconductor layer 14 will be located on the light incidence surface side. This is because this can restrain the damping of light caused by the masking effect. The order of stacking can be suitably selected on the basis of the light transmittance of each layer. However, according as the number of unit structures increases, it will be advantageous to construct the structure so that the layer having a higher light transmittance is located on the light incidence surface side.

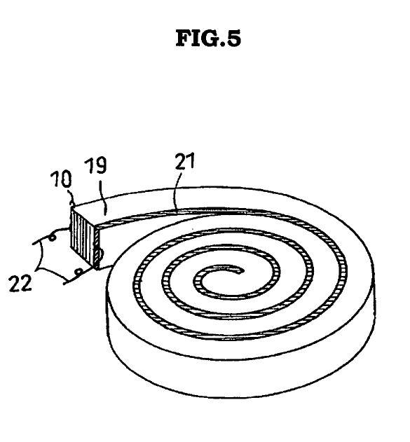

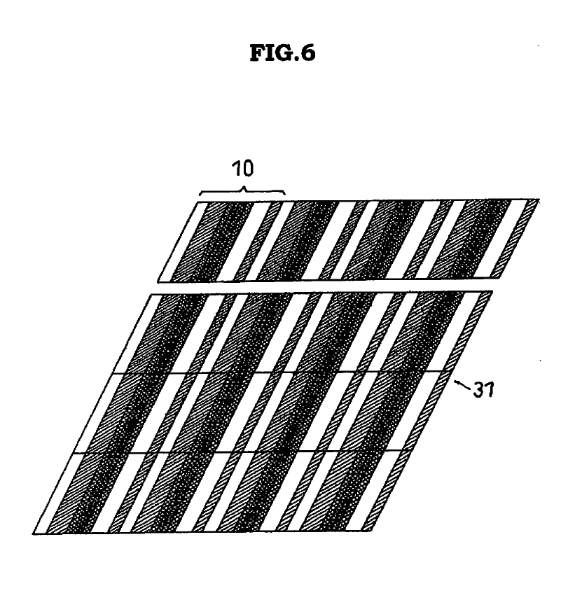

The aforesaid continuous stacking structure can be used as a more practical structure when the structure is wound like a roll with an intervention of an insulating film 21, as shown in FIG. 5, for example. The continuous stacking structure shown in FIG. 5 is one in which five layers each having the solar cell 10 as one unit are stacked. Also, in this continuous stacking structure, collection electrodes 22 respectively electrically connected to the first electrode 11 and the second electrode 12 are provided.

In the solar cell 10 according to the present embodiment, all of the positive/negative carriers generated in the neighborhood of the pn-junction 15 pass through the surface layer part of the cell irradiated with light (region into which the light can penetrate from the photoreceptive surface) to move respectively to the first electrode 11 and the second electrode 12 located to the right and left. The electric conductivity under irradiation with light (light conductivity) is extremely larger than the electric conductivity in a dark state (dark conductivity). Namely, the electric resistance is extremely low. By this, the internal resistance of the cell can be fundamentally reduced. This also applies in a similar manner in the case of the continuous stacking structure shown in FIG. 4.

Also, the efficiency of incidence of light to the active region can be greatly increased as compared with the case of a vertical structure, thereby improving the power generation efficiency. In this manner, the photoelectromotive force apparatus according to the present embodiment can fundamentally solve the great problems that the solar cell having a structure of being stacked to be parallel to the photoreceptive surface or the solar cells disclosed in Japanese Patent Application Laid-Open (JP-A) Gazette No. 2005-11841 have.

With a photoelectromotive force apparatus provided with solar cells according to the present embodiment, a photoelectric energy conversion efficiency of 10% or more, which was considered to be impossible in conventional semiconductor solar cells, can be achieved.

Next, a method of manufacturing a photoelectromotive force apparatus according to the present embodiment will be described. The method of manufacturing a photoelectromotive force apparatus according to the present embodiment includes the steps of stacking a first electrode 11 on a substrate; stacking a p-type semiconductor layer 13 on the first electrode 11; stacking an n-type semiconductor layer 14 on the p-type semiconductor layer 13 to form a pn-junction 15; stacking a second electrode 12 on the n-type semiconductor layer 14; and forming a solar cell 10 by cutting a stacked product formed through at least the aforesaid steps in a direction tilted at a predetermined angle relative to the front surface or the rear surface thereof so as to form the cut surface as a photoreceptive surface 16.

The step of stacking the first electrode 11 on the substrate is not particularly limited, so that various conventionally known methods such as the vapor deposition method and the coating method can be adopted. The substrate may be, for example, a glass substrate or a resin substrate made of epoxy resin or the like conventionally known in the art.

The step of stacking the p-type semiconductor layer 13 on the first electrode 11 is not limited to, for example, a deposition method such as the vapor deposition method or the sputtering method, so that a wet method such as the spin coating method or the bar coating method can be adopted.

When a wet method is adopted, a coating liquid prepared by dispersing an organic semiconductor at a predetermined ratio into a resin solvent is used. The resin solvent into which the organic semiconductor is dispersed is not particularly limited, and polymers for general use such as polycarbonate, polyvinylbutyral, polyvinyl alcohol, polystyrene, and polymethyl methacrylate, and electroconductive polymers such as polyvinylcarbazole, polymethylphenylsilane, and polydimethylsilane can be raised as examples. The p-type semiconductor layer 13 obtained by the wet method is formed into a film as a resin-dispersed organic semiconductor layer. If one wishes to attain a larger area of the solar cell 10, it is advantageous from the viewpoint of production efficiency to form a film of resin-dispersed organic semiconductor layer by the wet method.

The step of forming a film of the n-type semiconductor layer 14 on the p-type semiconductor layer 13 can be carried out basically in the same manner as the step of forming a film of the p-type semiconductor layer 13. Further, the step of stacking the second electrode 12 on the n-type semiconductor layer 14 is basically the same as the step of stacking the first electrode 11 on the substrate. Also, if a continuous stacking structure is to be formed, a desired stacked product can be obtained by repeatedly carrying out the above-described steps.

In the step of cutting the stacked product on the substrate, a method using a microtome can be adopted as shown in FIG. 6, for example. This forms the photoreceptive surface made of end surfaces of the first electrode 11, the second electrode 12, the p-type semiconductor layer 13, and the n-type semiconductor layer 14. In the case of cutting with a microtome, a resin substrate is preferably used as the aforesaid substrate, in view of the facility of cutting. However, as the present step, a method other than cutting with a microtome can also be adopted.

As shown in FIG. 6, in the cutting direction in cutting the stacked product, it is preferable to carry out the cutting from the end surface side of the stacked product 31 (in the direction perpendicular to the document sheet shown in FIG. 6). This is because, if the cutting is carried out from the front surface or rear surface side of the stacked product 31, the edge end of the blade goes into the interface of each layer at the time of cutting, thereby possibly generating the exfoliation of each layer. Also, the cutting of the stacked product is carried out by setting the cutting angle of a microtome to the stacked product 31 so that the angle formed by a normal line to the pn-junction 15 and a normal line to the cut surface is above or equal to 30° and below or equal to 60°. Further, in cutting the stacked product 31, it is preferable to carry out the cutting by fixing the stacked product 31. The fixation can be carried out, for example, by sandwiching the two surfaces of the stacked product 31 with rigid plastic plates or the like. Further, the cutting may be facilitated by forming cut-out parts in advance in the stacked product 31.

Here, in the present embodiment, description has been given using an organic semiconductor series photoelectromotive force apparatus as an example. However, the present invention is not limited to this alone. For example, the present invention can be applied to an inorganic semiconductor series or dye-sensitized type (Graetzel cell) solar cell having a junction interface. In particular, since the film can be easily formed by the vapor deposition method or the coating method, the present invention is suitably applied to two-layer hetero-junction type organic solar cells or bulk hetero-junction type solar cells having a pn-junction.

Hereafter, a preferable Example of the present invention will be described in detail in an exemplifying manner. However, the materials, the blending amounts, and the like described in this Example are not intended to limit the scope of the present invention to these alone and are merely examples for description, unless a specifically limitative description is given.

A solar cell according to the present Example was fabricated in the following manner. First, a film of a metal electrode layer made of platinum (Pt) was formed as a first electrode by the vacuum vapor deposition method on an epoxy resin substrate having a flat surface. The thickness thereof was set to be 2000 nm.

Next, vacuum vapor deposition was carried out on the first electrode using H₂Pc manufactured by Tokyo Kasei Kogyo Co., Ltd. as a material, so as to form a film of an H₂Pc layer as a p-type semiconductor layer. The thickness thereof was set to be 250 nm.

Subsequently, vacuum vapor deposition was carried out on the p-type semiconductor layer using Me-PTC manufactured by Dainichi Seika Industry Co., Ltd. as a material, so as to form a film of an Me-PTC layer as an n-type semiconductor layer. The thickness thereof was set to be 250 nm.

Further, an indium (In) film having a thickness of 100 nm and a silver (Ag) film having a thickness of 100 nm were successively formed on the n-type semiconductor layer by the vacuum vapor deposition method, so as to form a stacked film (In/Ag) as a second electrode.

Further, on the Me-PTC layer, a film of another metal electrode layer made of gold (Au) was formed as a metal electrode by the vacuum vapor deposition method. The thickness thereof was set to be 1 nm.

Next, on the other metal electrode layer made of gold (Au), vacuum vapor deposition was carried out using H₂Pc manufactured by Tokyo Kasei Co., Ltd. as a material, so as to form a film of an H₂Pc layer as a p-type semiconductor layer. The thickness thereof was set to be 250 nm.

Subsequently, vacuum vapor deposition was carried out on the p-type semiconductor layer using Me-PTC manufactured by Dainichiseika Color & Chemicals Mfg. Co., Ltd. as a material, so as to form a film of an Me-PTC layer as an n-type semiconductor layer. The thickness thereof was set to be 250 nm.

The steps of forming the other metal electrode layer made of gold, the p-type semiconductor layer, and the n-type semiconductor layer were repeated for nine times to form a sum of ten layers of the p-type-n-type stacked product.

Here, the reason why the metal electrode layer made of Pt was formed as the first electrode and the stacked film made of In/Ag was formed as the second electrode is for letting the work function of the first electrode be larger than the work function of the second electrode.

Next, vacuum vapor deposition was carried out on the second electrode using perylene-3,4,9,10-perylene-tetracarboxyl-bis-benzimidodazole (Im-PTC, see the following chemical structural formula) manufactured by Dainichiseika Color & Chemicals Mfg. Co., Ltd. as a material, so as to form a film of a protective layer having a thickness of 750 nm. The protective layer was provided to prevent exfoliation of the interface between the first electrode or the second electrode and the p-type semiconductor layer or the n-type semiconductor layer at the time of slicing (cutting) with a later-mentioned microtome.

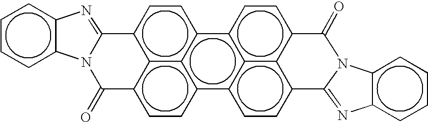

Next, with use of a microtome, the stacked product was cut from the end surface side thereof. Further, the stacked product was cut parallel to the cut surface so as to attain a thickness of 3 mm. The angle of cutting was set so that the normal line of the pn-junction would be 15°, 30°, 45°, 60°, 80°, or 90° relative to the normal line of the cut surface. This fabricated each of the solar cells (width of 2.5 mm) having a cut surface as a photoreceptive surface.

A pseudo solar light of 100 mW/cm² (AM 1.5) was radiated onto each of the fabricated solar cells. The rrent density (Jsc) and the open-ended shown in the following Table 1.

TABLE 1

| | Cutting angle | Short-circuit photocurrent | Open-ended |
|---|---|---|---|
| | (degrees) | density (mA/cm²) | voltage (V) |
| Example 1 | 15 | 20 | 3.1 |
| Example 2 | 30 | 23 | 3.2 |
| Example 3 | 45 | 28 | 3.2 |
| Example 4 | 60 | 26 | 3.2 |
| Example 5 | 80 | 22 | 3.1 |
| Comparative | 90 | 16 | 3.0 |
| Example 1 | | | |

What is claimed is:

1. A photoelectromotive force apparatus including a solar cell in which a p-type semiconductor layer and an n-type semiconductor layer are stacked as photoelectromotive force layers between a pair of electrodes that are disposed to oppose each other, wherein a pn-junction between said p-type semiconductor layer and said n-type semiconductor layer has an end side in a photoreceptive surface, and is tilted relative to the photoreceptive surface.

2. The photoelectromotive force apparatus according to claim 1, wherein an angle formed by a normal line to said pn-junction and a normal line to said photoreceptive surface is above or equal to 30° and below or equal to 60°.

3. The photoelectromotive force apparatus according to claim 1, wherein a plurality of said solar cells are stacked in series so that said pn-junctions will be parallel to each other.

4. The photoelectromotive force apparatus according to claim 1, wherein a material of said pair of electrodes is selected so that a work function of the electrode that is in contact with said p-type semiconductor layer will be larger than a work function of the electrode that is in contact with said n-type semiconductor layer.

5. The photoelectromotive force apparatus according to claim 1, wherein at least one of said p-type semiconductor layer and said n-type semiconductor layer is an organic semiconductor layer.

6. A method of manufacturing a photoelectromotive force apparatus, comprising the steps of:
stacking an electrode on a substrate;
stacking a p-type semiconductor layer on said electrode;
stacking an n-type semiconductor layer on said p-type semiconductor layer to form a pn-junction;
stacking another electrode on said n-type semiconductor layer; and
cutting a stacked product formed through at least said steps so that a cut surface will be tilted relative to a surface of the stacked product to form a photoreceptive surface.

7. The method of manufacturing a photoelectromotive force apparatus according to claim 6, wherein the step of cutting said stacked product is carried out by setting a cutting direction so that an angle formed by a normal line to said pn-junction and a normal line to said cut surface will be above or equal to 30° and below or equal to 60°.

8. The method of manufacturing a photoelectromotive force apparatus according to claim 6, wherein the step of cutting said stacked product is carried out from an end surface side of said stacked product.

9. A method of manufacturing a photoelectromotive force apparatus, comprising the steps of:
stacking an electrode on a substrate;
stacking a n-type semiconductor layer on said electrode;
stacking an p-type semiconductor layer on said n-type semiconductor layer to form a pn-junction;
stacking another electrode on said p-type semiconductor layer; and
cutting a stacked product formed through at least said steps so that a cut surface will be tilted relative to a surface of the stacked product to form a photoreceptive surface.

10. The method of manufacturing a photoelectromotive force apparatus according to claim 9, wherein the step of cutting said stacked product is carried out by setting a cutting direction so that an angle formed by a normal line to said pn-junction and a normal line to said cut surface will be above or equal to 30° and below or equal to 60°.

11. The method of manufacturing a photoelectromotive force apparatus according to claim 9, wherein the step of cutting said stacked product is carried out from an end surface side of said stacked product.
